(19) United States
(12) Patent Application Publication
(10) Pub. No.: US 2011/0175200 A1
(43) Pub. Date: Jul. 21, 2011

(54) MANUFACTURING METHOD OF CONDUCTIVE GROUP III NITRIDE CRYSTAL, MANUFACTURING METHOD OF CONDUCTIVE GROUP III NITRIDE SUBSTRATE AND CONDUCTIVE GROUP III NITRIDE SUBSTRATE

(75) Inventor: Takehiro YOSHIDA, Tsuchiura-shi (JP)

(73) Assignee: HITACHI CABLE, LTD., Tokyo (JP)

(21) Appl. No.: 12/814,728

(22) Filed: Jun. 14, 2010

(30) Foreign Application Priority Data
Jan. 21, 2010 (JP) 2010-011123

(51) Int. Cl. H01L 29/20; C30B 23/02; C30B 23/04; B26D 7/06

(52) U.S. Cl. 257/615; 117/95; 117/88; 83/23; 257/E29.089

(57) ABSTRACT

To provide a group III nitride crystal having sufficient conductivity and capable of growing in a short time, for growing the group III nitride crystal on a base substrate by vapor deposition at a growth rate of greater than 450 μm/hour and 2 mm/hour or less, by using a group III halogenated gas and NH₃ gas, wherein Ge is doped into the group III nitride crystal by suing GeCl₄ as a doping source, so that resistivity of the group III nitride crystal is 1×10⁻³ Ωcm or more and 1×10⁻² Ωcm or less.

### BACKGROUND OF THE INVENTION

1. Field of the Invention

The present invention relates to a manufacturing method of a conductive group III nitride crystal, a manufacturing method of a group III nitride substrate, and a conductive group III nitride substrate, and particularly to the manufacturing method of the conductive group III nitride crystal, the manufacturing method of the conductive group III nitride substrate, and the conductive group III nitride substrate for realizing a high output laser diode and a high luminance light emitting diode, or a high frequency electronic device.

2. Description of Related Art

A group III nitride semiconductor material, being a direct transition type, has a large forbidden band width, and therefore is suitable for application to a short wavelength light emitting element. In recent years, the group III nitride semiconductor material is used in a bluish-purple laser diode and green, blue, or white light emitting diodes, etc.

When the group III nitride semiconductor device is manufactured, there is no suitable substrate material with small lattice mismatch, and therefore a sapphire substrate is conventionally used. However, owing to not a small lattice mismatch, dislocation defect of about 10⁸ to 10¹⁰ per 1 cm² is introduced to the group III nitride semiconductor device mounted on the sapphire substrate. In addition, the sapphire substrate has a problem that electric conductivity and thermal conductivity are extremely inferior, and performance of the group III nitride device on the sapphire substrate is deteriorated.

In recent years, a single crystal Gallium Nitride substrate with about 10⁵ to 10⁶ dislocation density per 1 cm² is realized and is distributed in a market. By carrying out homoepitaxial growth on the single crystal Gallium Nitride substrate having no problem in electric conductivity and thermal conductivity, a device showing high performance can be easily obtained.

Most of the single crystal Gallium Nitride substrates distributed at present are manufactured by Halide Vapor Phase Epitaxy:HVPE) method. As measures for obtaining the single crystal Gallium Nitride substrate having electric conductivity by the above method, a method of supplying SiHₓCl₄₋ₓ (x=1 to 3) as doping gas (patent document 1), and a method of supplying O₂, H₂O, H₂S, SiCl₄, GeCl₄, Se₂Cl₂, Te₂Cl₂, etc, as doping gases (patent document 2), are known.

One sheet of heterogeneous substrate (such as gallium arsenide and sapphire) is consumed for obtaining one sheet of Gallium Nitride single crystal substrate which is distributed at present. Then, the surface of the heterogeneous substrate has various structures requiring labor in manufacture, for the purpose of protecting the heterogeneous substrate itself, reducing defects of the Gallium Nitride single crystal, and separating the Gallium Nitride single crystal from the heterogeneous substrate (patent document 3). For this reason, the Gallium Nitride single crystal substrate is extremely expensive. Therefore, at present, the Gallium Nitride single crystal substrate is exclusively applied to manufacture of the high output laser diode and is not generally used, which also prevents lower cost of the Gallium Nitride single crystal substrate.

Therefore, a technique of cutting a cost for preparing a base material and realizing lower cost of the Gallium Nitride single crystal substrate has been developed, by using the Gallium Nitride single crystal substrate as a seed crystal, then growing the Gallium Nitride single crystal having electric conductivity thick on the seed crystal to obtain ingot, and slicing the obtained ingot, to thereby manufacture the Gallium Nitride single crystal substrate (patent document 4).

In this case, the Gallium Nitride substrate is obtained by slicing a thick Gallium Nitride ingot by an inner peripheral blade slicer. Here, the Gallium Nitride substrate needs to have a thickness of 100 μm at lowest, for prevent breakage during handling. Meanwhile, slicing margin of several mm is needed per one cutting part (patent document 4). Further, a damage layer is introduced to the substrate obtained by slicing, and therefore the damage layer needs to be polished and removed. The polishing margin is several hundred μm per one side. Accordingly, the slicing margin and the polishing margin discarded simply as slicing dusts are several to ten times larger than a portion utilized as a substrate. Therefore, the ingot, being an origin of slicing, needs to have at least a length of cm order.

Therefore, a growth rate of the Gallium Nitride single crystal by HVPE method is problematic. However, generally the growth rate is only about 100 μm/hour (patent document 1, patent document 5, and non-patent document 1).

### (Patent Document 1)

Japanese Patent Laid Open Publication No. 2000-91234

### (Patent Document 2)

Japanese Patent Laid Open Publication No. 2006-193348

### (Patent Document 3)

Patent Publication No. 3985839

### (Patent Document 4)

Japanese Patent Laid Open Publication No. 2006-273716

### (Patent Document 5)

Japanese Patent Laid Open Publication No. 2003-17420

### (Non-Patent Document)

(Non-patent document 1) Kenji Fujito, Shuichi Kubo, Hirobumi Nagaoka, Tae Mochizuki, Hideo Namita, Satoru Nagao, Journal of Crystal Growth 311 (2009)3011

As described above, when the growth rate of the Gallium Nitride single crystal by HVPE method is about 100 μm/hour, several hours are required for growth of the quantity discarded as slicing dusts. Therefore, in a conventional method using the HVPE method, it is difficult to provide the Gallium Nitride substrate having sufficient conductivity at a low cost.

### BRIEF SUMMARY OF THE INVENTION

An object of the present invention is to provide a manufacturing method of a conductive group III nitride crystal capable of growing the group III nitride crystal having sufficient conductivity, and capable of reducing a manufacturing cost of the group III nitride substrate obtained by slicing the group III nitride crystal, and a manufacturing method of the conductive group III nitride substrate and the conductive group III nitride substrate.

According to an aspect of the present invention, a manufacturing method of a conductive group III nitride crystal is provided, for growing the group III nitride crystal on a base substrate by vapor deposition at a growth rate of greater than 450 μm/hour and 2 mm/hour or less, by using a group III halogenated gas and NH₃ gas, wherein Ge is doped into the group III nitride crystal by using GeCl₄ as a doping source, so that resistivity of the group III nitride crystal is 1×10⁻³ Ωcm or more and 1×10⁻² Ωcm or less.

In this case, the base substrate can be formed as a substrate, with a mask pattern formed on any one of sapphire, gallium arsenide, silicon, Gallium Nitride, aluminium nitride, or any one of base substrates of them.

Further, the group III nitride crystal is preferably AlₓIn_{y}Ga_{1-x-y}N (0≦x≦1, 0≦y≦1, 0x+y≦1) crystal.

Further, according to other aspect of the present invention, a manufacturing method of a conductive group III nitride substrate is provided, comprising:

acquiring the conductive group III nitride substrate by slicing the conductive group III nitride crystal grown by the aforementioned manufacturing method of the conductive group III nitride crystal, with an arbitrary crystal plane; and

setting a thickness to 100 μm or more and 600 μm or less by polishing both surfaces of the acquired conductive group III nitride substrate.

In this case, preferably a maximum absolute value of variation of carrier concentration in a principal surface of the conductive group III nitride substrate manufactured by the manufacturing method of the group III nitride substrate is 1% or more and 10% or less with respect to a mean value of the carrier concentration in the principal surface.

Further, according to another aspect of the present invention, a conductive group III nitride substrate doped with Ge is provided, wherein a maximum absolute value of variation of a carrier concentration in a principal surface of the substrate is 1% or more and 10% or less with respect to a mean value of the carrier concentration in the principal surface.

In this case, preferably the resistivity of the conductive group III nitride substrate is 1×10⁻³ cm or more and 1×10⁻² Ωcm or less.

Further, preferably the conductive group III nitride substrate is a AlₓIn_{y}Ga_{1-x-y}N (0≦x≦1, 0≦y≦1, 0≦x+y≦1) substrate.

Further, preferably a thickness of the conductive group III nitride substrate is 100 μm or more and 600 μm or less.

According to the present invention, a long ingot of the group III nitride having sufficient conductivity can be grown for a short time, and the manufacturing cost of the group III nitride semiconductor substrate obtained by slicing the ingot can be reduced.

### BRIEF DESCRIPTION OF THE DRAWINGS

FIG. 1 is a view showing a resistivity measurement result of a Gallium Nitride ingot according to a conventional example, wherein the Gallium Nitride crystal grows at a growth rate of 1 mm/hour in a state that a supply partial pressure of a doping source SiH₂Cl₂ is varied.

FIG. 2 is a view showing a resistivity measurement result of a Gallium Nitride ingot according to a conventional example, wherein the Gallium Nitride crystal grows in a state of constant supply partial pressure of the doping source SiH₂Cl₂ and varying the growth rate of the Gallium Nitride crystal.

FIG. 3 is a conceptual view of an HVPE apparatus used in an embodiment of the present invention.

FIG. 4 is a conceptual view for obtaining a substrate by slicing an ingot according to an embodiment of the present invention.

FIG. 5 is a view explaining a state that a sliced substrate includes an impurity concentration distribution for obtaining a surface shape of the ingot grown on a seed crystal according to an embodiment of the present invention.

FIG. 6 is a schematic view of the HVPE apparatus used in a conventional example and example 4.

FIG. 7 is a view showing the resistivity measurement result of a Gallium Nitride substrate of example 1.

FIG. 8 is a view showing the resistivity measurement result of the Gallium Nitride substrate of example 2.

FIG. 9 is a view showing the resistivity measurement result of the Gallium Nitride substrate of example 3.

FIG. 10 is a view showing a CL (cathode luminescence) observation result in example 4.

FIG. 11 is a view showing a measurement result of a carrier concentration distribution in example 4.

FIG. 12 is a view showing a measurement result of a carrier concentration distribution in example 5.

FIG. 13 is a view explaining a slice pattern in example 6.

FIG. 14 is a view showing the resistivity measurement result of the Gallium Nitride substrate of example 7.

FIG. 15 is a view showing the resistivity measurement result of the group III nitride crystal that grows by varying the growth rate, with the supply partial pressure of GeCl₄ according to an embodiment of the present invention set as a parameter.

FIG. 16 is a view showing the growth of the ingot on a base substrate with a mask pattern formed thereon according to other embodiment of the present invention.

### DETAILED DESCRIPTION OF THE INVENTION

### [Knowledge]

Inventors of the present invention try to grow a Gallium Nitride ingot by HVPE method, at a growth rate of 1 mm/hour which is about 10 times greater than that of a conventional example. At this time, doping of Si is tried under an impurity supply condition (SiH₂Cl₂ partial pressure 2×10⁻⁶ atm) similar to that of an example of patent document 1. However, the obtained Gallium Nitride ingot can not have sufficient conductivity.

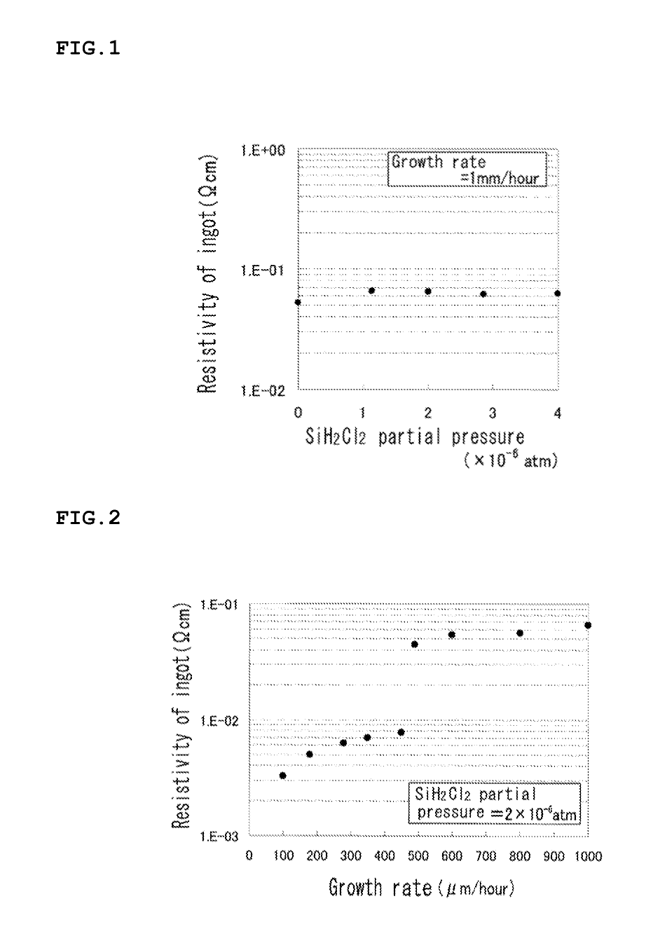

Further, as shown in FIG. 1, even if the partial pressure of supplied SiH₂Cl₂ is varied, unexpectedly no variation is observed in the resistivity of the obtained Gallium Nitride ingot.

Therefore, according to estimation by the inventors of the present invention, sufficient doping of Si is not performed when the Gallium Nitride ingot is grown at the growth rate of 1 mm/hour, due to high growth rate of 1 mm/hour.

In order to confirm the above-described estimation, actually the supply partial pressure of SiH₂Cl₂ was maintained to be constant to the same value as the value of the example of patent document 1, and the Gallium Nitride ingot was grown with the growth rate varied. Then, variation of the resistivity of the Gallium Nitride ingot obtained at this time was examined. As a result, as shown in FIG. 2, it was found that when the growth rate exceeded 450 μm/hour, the resistivity was increased suddenly.

The ingot with high resistivity and the ingot with low resistivity were examined and compared by Secondary Ion Mass Spectrometry:SIMS). As a result, it was found that concentration of Si was lower by 1 digit in the ingot with high resitivity than that of the ingot with low resistivity.

This is a great problem. When cost reduction is achieved by a method of obtaining the Gallium Nitride substrate by slicing the Gallium Nitride ingot, high growth rate is indispensable. However, in a method using SiH₂Cl₂, being a dopant source, sufficient conductivity can not be given to the ingot. In this state, it is difficult to supply the Gallium Nitride substrate having sufficient conductivity at a low cost.

Strenuous examination was performed by the inventors of the present invention, to find why the resistivity of the obtained ingot was increased, in other words, why Si concentration in the ingot was decreased, when the growth rate was increased.

As a result, it was found that there was a correlation between NH₃ partial pressure for growing the ingot and Si concentration in the ingot, wherein as the NH₃ partial pressure during growth was increased, the Si concentration in the obtained ingot was decreased. Under the condition that the growth rate becomes greater, supplying partial pressures of both group III source and NH₃ need to be increased, and therefore the resistivity of the ingot grown at a high rate is increased.

As the NH₃ partial pressure becomes higher, doping of Si becomes difficult, and the reason therefore is considered as follows. Namely, SiH₂Cl₂ and NH₃ used as doping sources, are reacted in a vapor phase before they reach the surface of the seed substrate.

In order to prevent such a situation, the inventors of the present invention consider it appropriate to change the source used in doping, to the source less decomposed than SiH₂Cl₂, in other words, the source with high decomposition temperature and hardly reacted with NH₃.

The inventors of the present invention searched the doping source that matched such a condition. As a result, it was found that GeCl₄ was suitable.

### An Embodiment

An embodiment of the present invention will be specifically described hereafter.

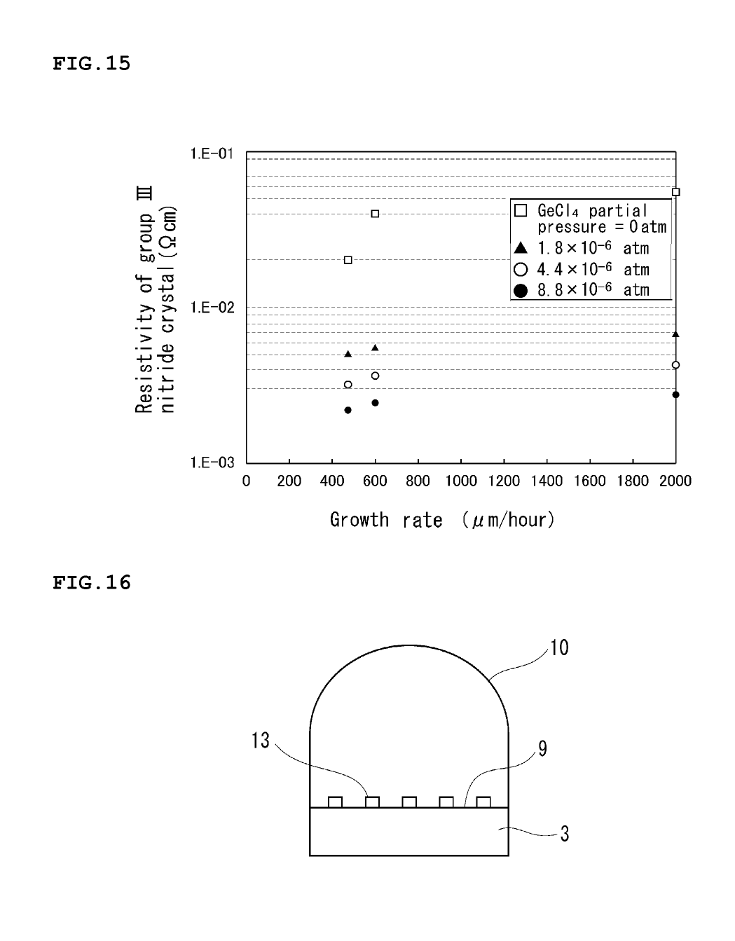

According to an embodiment of the present invention, when the group III nitride crystal is grown on the base substrate, being the seed crystal, at the growth rate in a range of greater than 450 μm/hour and 2 mm/hour or less by using the group III halogenated gas and NH₃ gas, doping of Ge is enabled by using GeCl₄ as the doping source, and the conductive group III nitride crystal with resistivity of 1×10⁻³Ω or more and 1×10⁻² Ωcm or less for giving sufficient conductivity to the ingot is enabled (examples 1 to example 3, and FIG. 15).

### (Base Substrate)

The long ingot of the group III nitride single crystal was grown on the base substrate, being the seed crystal, by using the HVPE method. The Gallium Nitride substrate or the aluminium nitride substrate is suitably used in the base substrate. However, the substrate with a mask pattern formed on any one of sapphire, gallium arsenide, silicon, Gallium Nitride, aluminium nitride, or any one of base substrates of them, can also be used.

### (HVPE Apparatus)

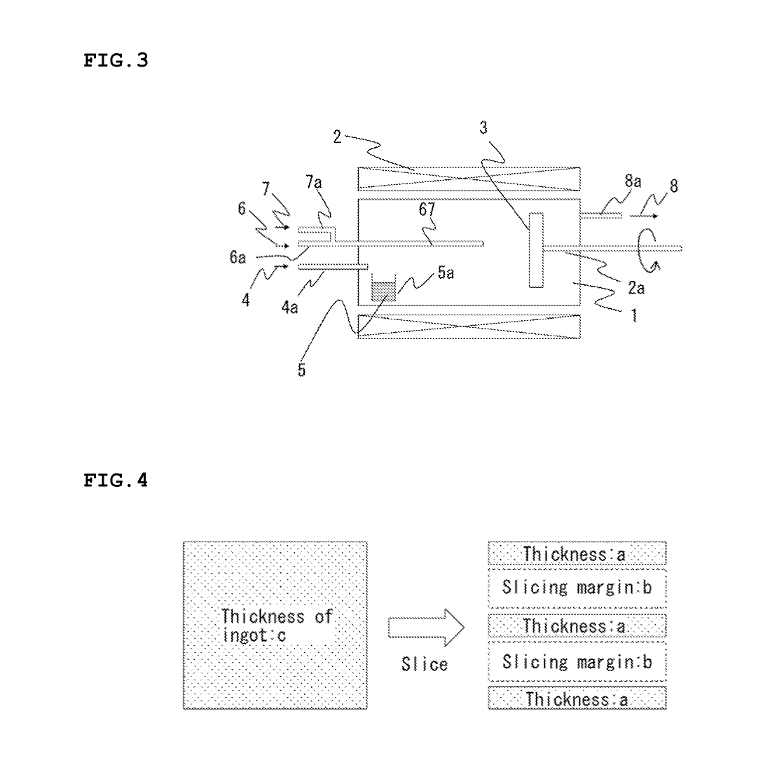

A schematic view of the HVPE apparatus is shown in FIG. 3. The HVPE apparatus is a so-called hot-wall apparatus having a heater 2 on the outer periphery of a reaction tube 1 made of quartz. A boat 5a storing group III metal source 5 is provided to inside of the reaction tube 1. Further, shaft 2a having a rotation mechanism is introduced to inside of the reaction tube 1. Mixed gas supply line 67 in which first supply line 7a and second supply line 6a are integrated, and third supply line 4a are connected to the reaction tube 1. Doping gas 7 is supplied from the first supply line 7a, and group V source gas 6 is supplied from the second supply line 6a, and these gases are mixed and supplied to the inside of the reaction tube 1 from the mixed gas supply line 67. Moreover, halogen gas 4 is supplied to group III metal source 5 stored in the boat 5a inside of the reaction tube 1 from the third supply line 4a. Further, exhaust line 8a is connected to the reaction tube 1, so that exhaustion 8 of inside of the reaction tube 1 is performed.

Seed crystal 3 is fixed to the shaft 2a having the rotation mechanism. The long ingot of the group III nitride single crystal having conductivity is grown, by exhausting the group III source gas generated by supplying halogen gas 4 to the group III metal source 5, NH₃ gas, being group V source gas 6, and GeCl₄ gas, being doping gas 7, from the exhaust line 8, while spraying these gases to the seed crystal 3 while rotating the seed crystal 3. Length of the ingot is set to cm order such as 1.5 cm and 2.0 cm.

The group III source gas is the group III halogenated gas and is generated by supplying HCl gas to the metal source 5 such as In, Al, or Ga heated to about 500° C. to 900° C. The group III halogenated gas is, for example, InCl, AlCl, or GaCl. The group III nitride crystal is, for example, AlₓIn_{y}Ga_{1-x-y}N (0≦x≦1, 0≦y≦1, 0≦x+y≦1) crystal. Specifically, the group III nitride crystal is InN, AlN, or GaN. NH₃ gas, being group V source gas 6, and GeCl₄ gas, being doping gas 7, are mixed and supplied to the reaction tube 1.

Source vessels (not shown) of these NH₃ gas, GeCl₄ gas, and HCl gas are set in parallel, and the ingot with a desired composition is grown by adjusting a supply molar ratio. The temperature of a group III nitride single crystal growth part excluding the seed crystal 3 is suitably set in a range of 500° C. to 1100° C. in matching with a growth object by controlling the heater 2.

### (Slicing)

The grown ingot is sliced into substrates, each having thickness “a” as shown in FIG. 4, by using the inner peripheral blade slicer. When portions of thickness “b” are lost as the slicing margin, most economical thickness “c” of the ingot for obtaining x sheets of substrates is expressed by:

C=ax+(x−1)b (Formula 1).

Accordingly, in consideration of the thickness “a” of each sliced substrate, the number of sheets “x”, and the slicing margin “b”, preferably the thickness “c” of the ingot to be grown is obtained in advance by (Formula 1), and based on this formula, the ingot is grown.

Here, when the growth rate of the ingot is set to “r”, and total time of setup time and temperature increase/decrease time required for growing the ingot by the HVPE method is set to T, growth time dₓ in terms of one sheet of substrate can be obtained as

dₓ=((c/r)+T)/x (Formula 2)

The growth time dₓ per one substrate may be shortened for reducing the cost. However, there is a limit in shortening the total time T of the setup time and temperature increase/decrease time, even if efficiency of the total time T is achieved. Therefore, in order to reduce an influence of the total time T of the setup time and the temperature increase/decrease time required for growing the ingot, the thickness “c” of the ingot is increased, namely, the length of the ingot is increased, and the number of slicing sheets “x” is increased.

### (Growth Rate)

However, it should be noted that when (Formula 1) is substituted in (Formula 2) and the relation of “r”, “b”, and “T” is arranged based on the assumption that the growth time in terms of one sheet of substrate is shorter in a case of “x” sheets than the growth time in a case of “x−1” sheets (dₓ<dₓ₋₁),

R>b/T

is introduced. Accordingly, it is found that the growth time “d” can not be shortened, unless the (Formula 3) is satisfied.

Generally required growth rate was examined, and it was found that when the inner peripheral blade slicer was used, the slicing margin “b” was approximately around 1 mm. “T” was about 2 hours and a half in a case of efficiency is achieved. Then, from the (Formula 3), it is found that growth rate “r” greater than 400 μm/hour is needed for the ingot growth.

As the growth rate “r” becomes greater than 400 μm/hour, the growth time “d” in terms of one sheet of substrate is easily decreased by increasing the length of the ingot. However, in order to actually grow the ingot normally without problem, an upper limit of “r” is 2 mm/hour at most. Further, in a range of 400 μm/hour<r≦450 μm/hour, there is a possibility that Si concentration is high even in a conventional technique using a silane-based doping gas. Therefore, when the doping gas of GeCl₄ is used, a lower limit of “r” is a value greater than 450 μm/hour. Accordingly, the growth rate of the ingot is preferably applied in a range of 450 μm/hour<r≦2 mm/hour.

### (Substrate Thickness)

The substrate is sliced so as to obtain thickness “a”. In order to remove a damage layer introduced by slicing and make front/rear surfaces flat, polishing process is applied to the front/rear surfaces, and about 100 μm of the damage layer is removed respectively. The thickness of the group III nitride substrate thus obtained is preferably 100 μm or more and 600 μm or less. 100 μm or more is selected, because the thickness of 100 μm is required at lowest for handling without breaking the substrate. Also, 600 μm or less is selected, because when the substrate becomes thicker than 600 μm, cleavage executed after preparing the device is difficult and a removing amount is increased by back lapping, thus having an adverse influence on productivity.

### (Impurity Concentration)

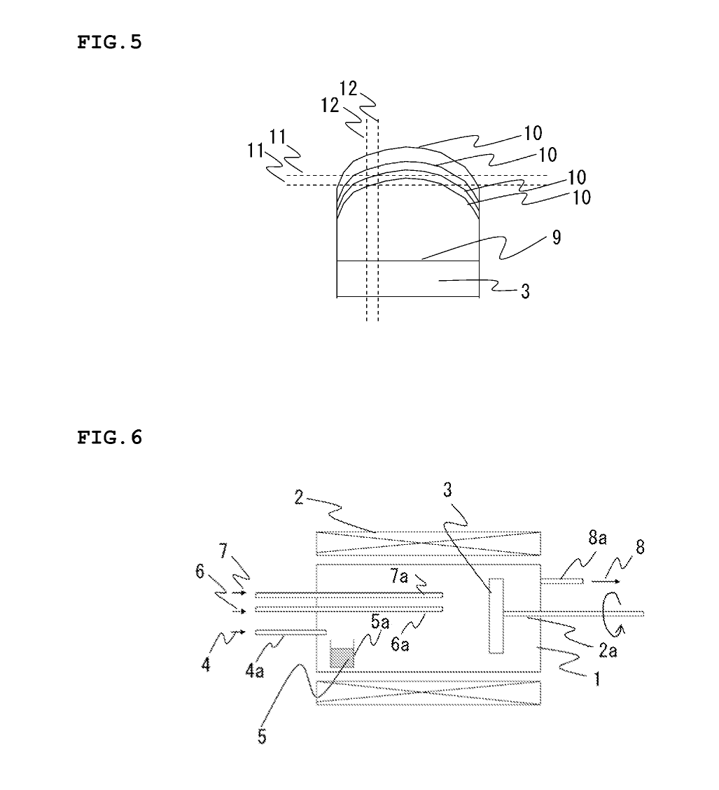

When the ingot is grown, the seed crystal is rotated. Therefore, a periodic impurity concentration distribution exists in a depth direction of the ingot. Further, the growth rate is not completely uniform over an entire body of a growth area. Therefore, as shown in FIG. 5, surface 9 of the seed crystal and crystal surfaces 10 during ingot growth are not parallel to each other. The impurity concentration distribution exists periodically in parallel to the crystal surfaces 10 shown in FIG. 5 during ingot growth. The ingot is sliced with slice surfaces 11 parallel to the surface 9 of the seed crystal, and slice surfaces 12 orthogonal to the surface 9 of the seed crystal, to thereby obtain the group III nitride substrate having a desired crystal orientation. Therefore, impurity concentration distribution is included in such surfaces.

FIG. 6 shows a conventional HVPE apparatus using the silane-based doping gas. A different point of the HVPE apparatus shown in FIG. 6 from that of FIG. 3 is that the first supply line 7a and the second supply line 6a are not integrated and are connected to the inside of the reaction tube 1 in a state of being separated, so that the doping gas 7 and the group V source gas 6 are separately supplied to the inside of the reaction tube 1. As is found from this structure, conventionally, the silane-based doping gas and NH₃ are not mixed sufficiently and are supplied to the inside of the reaction tube 1. This is because the silane-based doping gas has a property that the doping gas itself is decomposed at upstream part and a reaction between the doping gas and NH₃ is vigorous. Therefore, in the conventional method using the silane-base doping gas, the silane-based doping gas can not be supplied in a state of being sufficiently mixed with the group V source gas. Therefore, the impurity concentration distribution of the group III nitride substrate is wide.

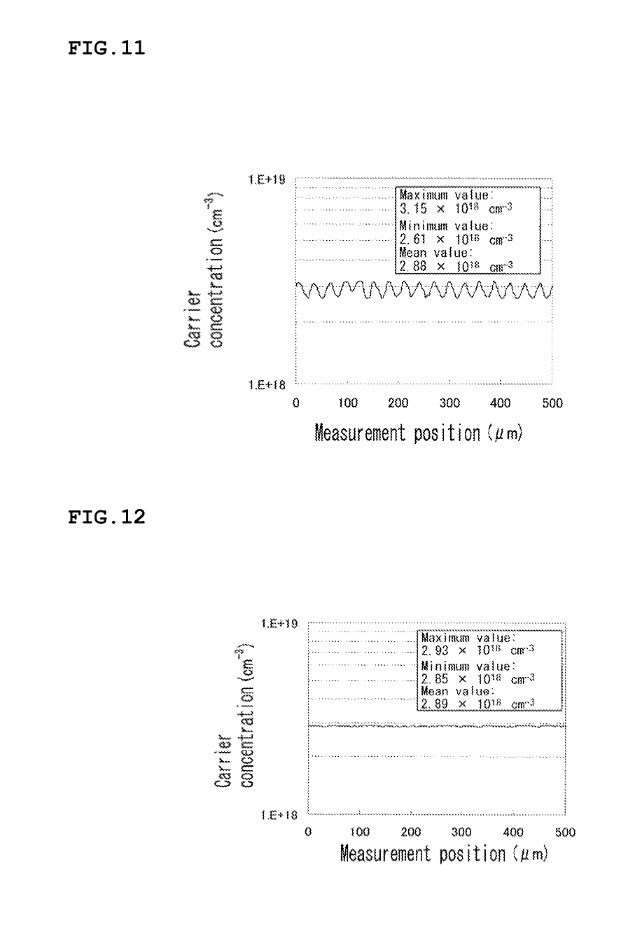

However, in an embodiment of the present invention, GeCl₄ is used as the doping gas, which is hardly decomposed at the upstream part and is hardly reacted with NH₃. Therefore, the doping gas can be supplied in a state of being sufficiently mixed with the group V source gas 6, and therefore the impurity concentration distribution (distribution of Ge in this case) can be made small. Although depending on the growth condition, when the doping gas is supplied in a state of being sufficiently mixed with the group V source gas, the variation of the Ge concentration in the surface of the substrate can be reduced. Therefore, the maximum absolute value of the variation of the carrier concentration in the principal surface of the group III nitride substrate can be reduced to about 1% of the mean value of the carrier concentration in the principal surface (FIG. 12 of example 5). Even when the doping gas and the group V source gas are separated and supplied as usual as shown in FIG. 6, the maximum absolute value of the variation of the carrier concentration in the principal surface of the group III nitride substrate can be set to about 10% of the mean value of the carrier concentration in the principal surface (FIG. 11 of example 4).

Thus, in the method of this embodiment using GeCl₄ as the doping gas, the conductive group III nitride crystal with smaller variation of the carrier concentration in the surface of the substrate than conventional can be grown.

In the substrate with the aforementioned mask pattern formed thereon, for example as shown in FIG. 16, a mask layer 13 having an opening part is formed on the base substrate, and the group III nitride single crystal is laterally grown through the mask layer having the opening part.

### Effects of the Embodiment

According to an embodiment of the present invention, one or more effects are exhibited as follows.

According to an embodiment of the present invention, GeCl₄ is used as the doping source. Therefore, even if the conductive group III nitride crystal is grown at a high growth rate of greater than 450 μm/hour and 2 mm/hour or less, the conductive group III nitride semiconductor crystal having low resistivity of 1×10⁻³ Ωcm or more and 1×10⁻² Ωcm or less can be grown.

Further, the resistivity is low, such as 1×10⁻³ Ωcm or more and 1×10⁻² Ωcm or less. Therefore, the group III nitride crystal having sufficient conductivity can be grown.

Further, the group III nitride crystal is grown at the growth rate of greater than 450 μm/hour and 2 mm/hour or less. Therefore, the long ingot can be grown for a short time at a low cost.

Further, GeCl₄ is used as the doping source. Therefore, the variation of the impurity concentration is low and the group III nitride substrate with small resistivitiy distribution can be prepared.

Further, the ingot can be grown for a short time. Therefore, the manufacturing cost of the group III nitride semiconductor substrate obtained by slicing the ingot can be reduced.

Further, the ingot can be grown for a short time. Therefore, the conductive group III nitride semiconductor substrate can be provided at a low cost, which is required for realizing the high output laser diode, high luminance light emitting diode, or high frequency electronic device.

Further, the base substrate can be applied not only to the Gallium Nitride substrate, but also to sapphire, gallium arsenide, silicon, or aluminium nitride. Further, the base substrate can also be applied to the substrate with mask pattern formed on these base substrates. Accordingly, the manufacturing cost can be reduced even if the base substrate other than the Gallium Nitride substrate is used.

Further, the group III nitride crystal can be realized even by AlₓIn_{y}Ga_{1-x-y}N (0≦x≦1, 0≦y≦1, 0≦x+y≦1) crystal other than GaN. Sufficient conductivity can also be given to the group III nitride crystal other than GaN.

Further, when the thickness of the group III nitride substrate is 100 μm or more, breakage of the substrate during handling can effectively be prevented, and when the thickness is 600 μm or less, the cleavage executed after preparing the device is facilitated, and therefore the removing amount can be reduced even in a case of executing back lap. Accordingly, when the thickness of the group III nitride substrate is 100 μm or more and 600 μm or less, the manufacturing cost can be further reduced.

Further, when the maximum absolute value of the variation of the carrier concentration is 1% or more and 10% or less of the mean value of the carrier concentration in the principal surface, a group III nitride device with high quality and high performance can be obtained.

In addition, as a matter of course, the present invention can be variously modified in a range not departing from the gist of this invention.

### EXAMPLES

### Example 1

Gallium Nitride single crystal (0001) with a diameter of 56 mm and a thickness of 400 μm was used as the seed crystal, and the ingot of the Gallium Nitride was grown by the HVPE method. At this time, the growth was carried out with the supply partial pressure of GaCl gas set to 3×10⁻² atm, the supply partial pressure of the NH₃ gas set to 20×10⁻² atm, and the supply partial pressure of the H₂ gas, being the carrier gas, set to 25×10⁻² atm. The growth area was set in a range of diameter 52 mm. The growth rate at this time was 600 μm/hour.

The NH₃ gas and the GeCl₄ gas were mixed and introduced to the HVPE apparatus (FIG. 3). At this time, the supply partial pressure of the GeCl₄ gas was set to any one of 0 atm, 1.8×10⁻⁶ atm, 4.4×10⁻⁶ atm, 8.8×10⁻⁶ atm, and the Gallium Nitride ingot was grown respectively under the aforementioned condition. The thickness was set to 3 mm. From tip parts of all obtained ingots, a Gallium Nitride plate, with plane orientation of the principal surface being (0001), having a thickness of 600 μm was sliced by using the inner peripheral blade slicer. Mirror surface polishing process was applied to the front/rear surfaces of the substrate, to thereby obtain the Gallium Nitride substrate of 400 μm.

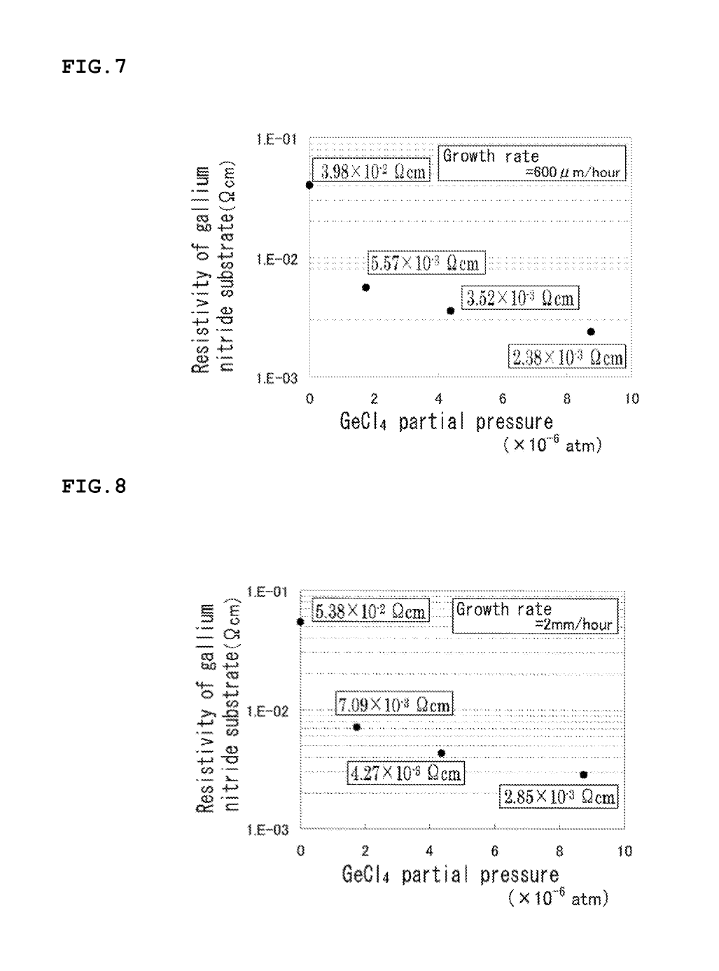

The resistivity of the obtained Gallium Nitride substrate was examined and a result thereof was shown in FIG. 7. The resistivity was evaluated by a four probe method. The center of the substrate was set as a measurement place. When the supply partial pressure of the doping gas GeCl₄ was 0 atm, 1.8×10⁻⁶ atm, 4.4×10⁻⁶ atm, and 8.8×10⁻⁶ atm, the resistivity of the Gallium Nitride substrate was 3.98×10⁻² Ωcm, 5.57×10⁻³ Ωcm, 3.52×10⁻³ Ωcm, 2.38×10⁻³ Ωcm respectively. It was found that even under a high growth rate condition of 600 μm/hour, the resistivity of the obtained ingot could be controlled by the supply partial pressure of GeCl₄. Then, by using GeCl₄ as the doping gas, the resistivity of the Gallium Nitride substrate could be set in a range of 1×10⁻³ Ωcm or more and 1×10⁻² Ωcm or less if the partial pressure of GeCl₄ was set to about 1×10⁻⁶ atm or more and 8.8×10⁻⁶ atm or less.

### Example 2

The ingot of the Gallium Nitride was grown under the same condition as the example 1, excluding a point that in the example 1, the supply partial pressure of the GaCl gas was set to 6×10⁻² atm, the supply partial pressure of the NH₃ gas was set to 35×10⁻² atm, and the growth rate was set to 2 mm/hour, and the Gallium Nitride substrate was sliced from the ingot, to thereby obtain the Gallium Nitride substrate. The thickness of the Gallium Nitride substrate was set to 400 μm in the same way as the example 1. The result of examining the resistivity of the obtained Gallium Nitride substrate is shown in FIG. 8. It was found that the resistivity of the obtained ingot could be controlled by the supply partial pressure of GeCl₄, even under the high growth rate condition of 2 mm/hour. Then, by using GeCl₄ as the doping gas, the resistivity of the Gallium Nitride substrate could be set in a range of 1×10⁻³ Ωcm or more and 1×10⁻² Ωcm or less if the partial pressure of GeCl₄ was set to about 1.2×10⁻⁶ atm or more and 8.8×10⁻⁶ atm or less.

### Example 3

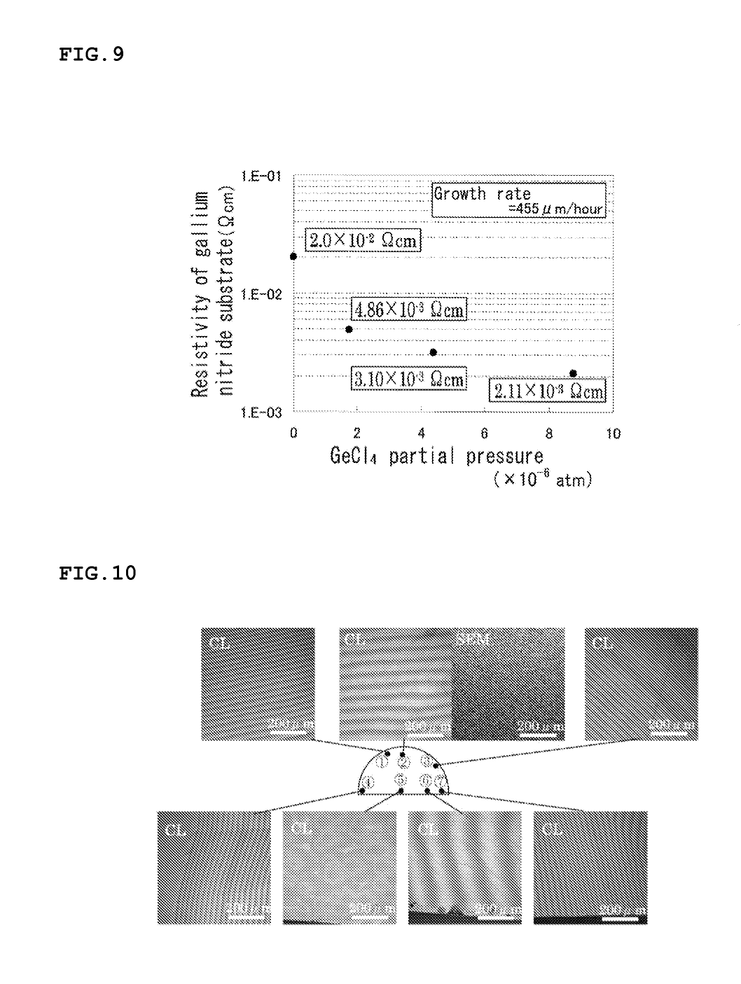

The ingot of the Gallium Nitride was grown under the same condition as the example 1, excluding a point that in the example 1, the supply partial pressure of the GaCl gas was set to 2×10⁻² atm, the supply partial pressure of the NH₃ gas was set to 13×10⁻² atm, and the growth rate was set to 455 μm/hour, and the Gallium Nitride substrate was sliced from the ingot, to thereby obtain the Gallium Nitride substrate. The thickness of the Gallium Nitride substrate was set to 400 μm in the same way as the example 1. The result of examining the resistivity of the obtained Gallium Nitride substrate was shown in FIG. 9. It was found that the resistivity of the obtained ingot could be controlled by the supply partial pressure of GeCl₄, even under the high growth rate condition of 455 μm/hour. Then, by using GeCl₄ as the doping gas, the resistivity of the Gallium Nitride substrate could be set in a range of 1×10⁻³ Ωcm or more and 1×10⁻² Ωcm or less if the partial pressure of GeCl₄ was set to about 0.6×10⁻⁶ atm or more and 8.8×10⁻⁶ atm or less.

### Conclusion of Examples 1 to Example 3

FIG. 7 to FIG. 9 showing measurement results of the example 1 to the example 3 were summarized in one view by setting the supply partial pressure of GeCl₄ as a parameter, to thereby prepare FIG. 15 showing the resistivity measurement result of the group III nitride crystal with respect to the growth rate. From FIG. 15, it was found that when GeCl₄ was used as the doping source, the conductive group III nitride crystal, with the resistivity satisfying 1×10⁻³ Ωcm or more and 1×10⁻² Ωcm or less, could be grown even if the group III nitride crystal was grown at a high rate of greater than 450 μm/hour and 2 mm/hour or less.

### Comparative Example 1

The ingot of the Gallium Nitride was grown under the same condition as the example 1, excluding a point that in the example 1, the supply partial pressure of the GaCl gas was set to 6.3×10⁻² atm, the supply partial pressure of the NH₃ gas was set to 36×10⁻² atm, and the growth rate was set to 2.1 mm/hour. Generation of a minute crack was observed in the ingot under the condition that the growth rate was set to 2.1 mm/hour. Accordingly, under the condition that the growth rate exceeds 2.0 mm/hour, it was found that the manufacturing method of the Gallium Nitride substrate using GeCl₄ as the doping gas was not appropriate.

### Example 4

The ingot of the Gallium Nitride was grown under the same condition as the example 1, excluding the thickness of the ingot and the supply partial pressure of GeCl₄ and the HVPE apparatus in the example 1. The thickness of the grown ingot was set to 15 mm, being a length of cm order, and 10 sheets of the Gallium Nitride substrate having a thickness of 600 μm were acquired by using the inner peripheral blade slicer (slicing margin 1 mm). At this time, the NH₃ gas and the GeCl₄ gas were separately introduced to the HVPE apparatus (FIG. 6). The supply partial pressure of GeCl₄ was set to 1.8×10⁻⁶ atm.

10 sheets of Gallium Nitride substrate with a thickness of 600 μm, diameter of 52 mm and a principal surface of (0001) were obtained from the ingot of 15 mm, by using the inner peripheral blade slicer. In the same way as the example 1, mirror surface polishing was applied thereto, to thereby set a thickness to 400 μm. The resistivity of all substrates was 5.6×10⁻³ Ωcm. Namely, even when the thickness of the ingot was a cm order length and GeCl₄ and NH₃ were separately supplied, the resistivity of the Gallium Nitride substrate could be set in a range of 1×10⁻³ Ωcm or more and 1×10⁻² Ωcm or less.

Cathode luminescence (CL) mapping image observation was performed to a disc-shaped Gallium Nitride substrate thus obtained, at seven places (shown by 1 to 7 in circles) corresponding to approximately semicircular outer peripheral part of a substrate surface. A panchromatic detector was used for the observation. Then, as shown in FIG. 10, bright and dark stripe patterns were observed concentrically. It can be considered that such bright and dark stripe patterns reflect the distribution of the carrier concentration, and the Gallium Nitride substrate has a Ge concentration distribution (variation of Ge concentration) of such a distribution. Further, detailed evaluation of this carrier concentration distribution was examined by a microscopic Raman spectroscopy method. Ar laser with a wavelength of 457.9 nm was used as a light source, and a spot size of measurement was set to 2 μm. As a result of performing line scanning in a diameter direction of the substrate, it was found that the variation of the carrier concentration was within ±10% in the surface of the substrate, namely the maximum absolute value of the variation of the carrier concentration was 10% in the substrate surface with respect to the mean value of the carrier concentration in the principal surface. An example of the measurement result was shown in FIG. 11. FIG. 11 shows a result of performing line scanning to the outer peripheral part of the Gallium Nitride substrate, specifically from a point near \textcircled{1} shown in FIG. 10 in a diameter direction of the substrate, wherein the horizontal axis shows a distance from this point.

In this example, 30 minutes were required for introducing the seed crystal and taking out it after growth, and 1 hour was required for increasing the temperature from a room temperature to a growth temperature, and 1 hour was required for decreasing the temperature from the growth temperature to the room temperature. The growth time was 24 hours and 20 minutes. Accordingly, 2 hours and 41 minutes were required for the growth per one substrate. The growth time per one Gallium Nitride substrate could be tremendously shortened and the conductive Gallium Nitride substrate having sufficient conductivity could be provided at a low cost.

### Example 5

The ingot was grown under the same condition as the example 4 excluding a point that in the example 4, GeCl₄ gas was mixed into NH₃ gas and a mixture was introduced to the HVPE apparatus (FIG. 3), to thereby obtain the Gallium Nitride single crystal substrate, and the resistivity of the substrate was measured. Then, the same result 5.6×10⁻³ Ωcm as the example 4 was obtained. Since GeCl₄ gas was mixed into NH₃ gas and the mixture was introduced to the HVPE apparatus. Therefore, the variation of the carrier concentration was about ±1% in the substrate surface, namely the maximum absolute value of the variation of the carrier concentration was 1% in the substrate surface with respect to the mean value of the carrier concentration in the principal surface. An example of the measurement result was shown in FIG. 12. Further, in this example as well, 2 hours and 41 minutes were required for the growth of one substrate, similarly to the example 4.

### Example 6

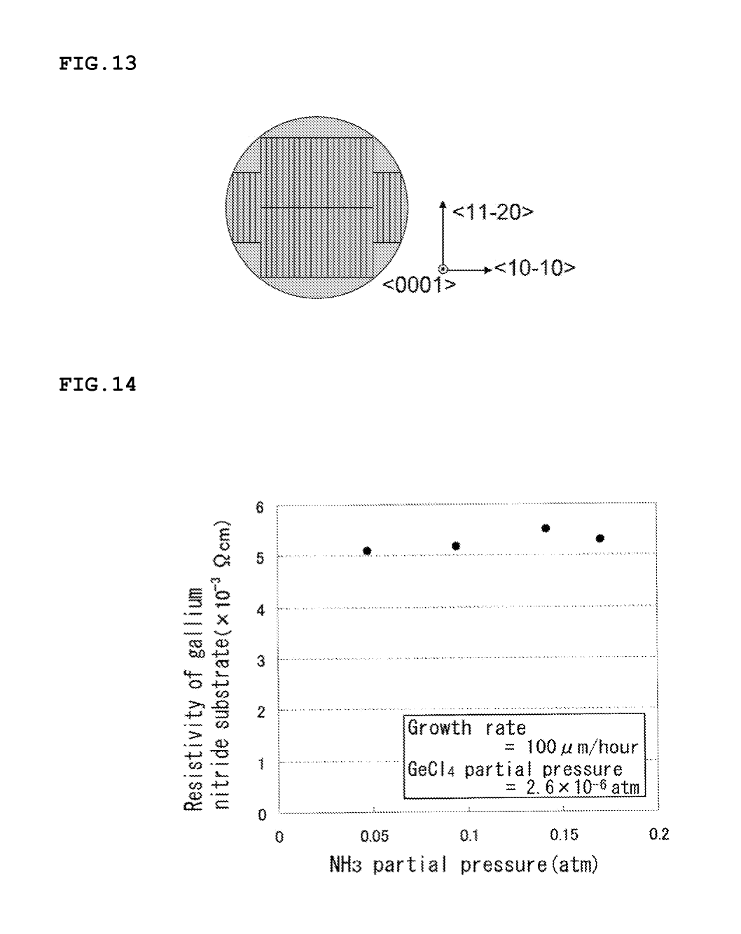

The ingot of 20 mm longer than the example 5 was grown under the same condition as the example 5, excluding a point that crystal growth time was extended in the example 6. 50 sheets of Gallium Nitride single crystal plates with 20 mm square, a thickness of 600 μm, and a principal surface of (10-10) were obtained from the ingot of diameter 52 mm and thickness of 20 mm, by using the inner peripheral blade slicer). As shown in FIG. 13, 20×20 sheets were sliced under a back-to-back state from the center part, and 5×5 sheets were sliced from right and left, in a plan view of the ingot. Thus, 50 sheets of Gallium Nitride single crystal substrates, with 20 mm square, thickness of 400 μm, and principal surface of (10-10) were obtained. The resistivity of all substrates was 5.6×10⁻³ Ωcm, which is the same as that of examples 5 and 6.

### Example 7

The Gallium Nitride ingot was grown in the example 1, with the supply partial pressure of GeCl₄ set to 2.6×10⁻⁶ atm, the supply partial pressure of NH₃ gas set to any one of 4.8×10⁻² atm, 9.5×10⁻² atm, 14.3×10⁻² atm, and 17×10 ² atm. The supply partial pressure of GaCl gas was adjusted in a range of 5×10⁻² atm to 8×10⁻² atm, so that the growth rate was set to a low rate of 100 μm/hour as conventional. In this way, similarly to the example 1, the Gallium Nitride ingot with a thickness of 3 mm was grown and the Gallium Nitride substrate was sliced, to thereby obtain the Gallium Nitride substrate of 400 μm.

A result of examining the resistivity of the obtained Gallium Nitride substrate was shown in FIG. 14. When GeCl₄ was used as the doping gas, it was found that there was only a slight variation in the resistivity of the obtained Gallium Nitride substrate (ingot), even if the NH₃ partial pressure was varied from 0.048 atm to 0.17 atm, namely in a range of 5.1×10⁻³ Ωcm to 5.5×10⁻³ Ωcm. This reveals that by using GeCl₄ as the doping gas, conductivity can be given to the ingot manufactured under a low growth rate condition of 450 μm or less.

The same thing can also be said for other group III nitride semiconductor that grows by using NH₃ source. As the group III source at this time, aluminium chloride, indium chloride, and gallium chloride were supplied, with partial pressures suitably adjusted, so that the group III ingot nitride having a desired composition could be obtained. For example, when InN ingot was grown, the Gallium Nitride single crystal substrate was used as the seed crystal, and when the ingot of AlN or AlInGaN was grown, the aluminium single crystal substrate was used as the seed crystal.

### Example 8

The similar experiment as the example 1 was executed, using the Gallium Nitride single crystal substrate with sapphire, gallium arsenide, and silicon formed on the base substrate and a mask pattern formed on the base substrate (see FIG. 16), as the seed crystal. As a result, the result similar to the example 1 was obtained.

### Comparative Example 2

Gallium arsenide (111) substrate was used as the base substrate and the Gallium Nitride single crystal was grown thereon by the HVPE method. First, the Gallium Nitride single crystal was grown at 500° C. for 1 hour, with the supply partial pressure of GaCl set to 2×10⁻² atm, the supply partial pressure of NH₃ set to 4.8×10⁻², and the supply partial pressure of H₂ set to 0.1 atm, and thereafter substrate temperature was increased to 1050° C., and the growth was continued for 1 hour under the same condition. Further, the GaCl partial pressure was increased to 8×10⁻² atm and the growth was continued for 1 hour, and thereafter the growth was continued for further 5 hours while supplying SiH Cl₂ gas at a partial pressure of 2×10⁻⁶ atm. After growth, the gallium arsenide substrate was ground and removed, to thereby obtain a Gallium Nitride free-standing substrate with a thickness of 600 μm. Thereafter, mirror surface polishing was applied to the front/rear surfaces, to thereby obtain the Gallium Nitride substrate having 400 μm. When the resistivity of the obtained substrate was evaluated by the four probe method, it was found that the resistivity was 3.3×10⁻³ Ωcm, which fell in a range of 1×10⁻³ Ωcm or more and 1×10⁻² Ωcm or less. Further, the carrier concentration distribution in the surface of the obtained substrate was examined by the microscopic Raman spectroscopy method. Ar laser with a wavelength of 457.9 nm was used as the light source, and the spot size for measurement was set to 2 μm. As a result of performing the line scanning in the diameter direction of the substrate, it was found that the variation of the carrier concentration was more inferior than those of examples 4 and 5, and ±33% in the surface of the substrate.

Further, the setup time was 30 minutes, which was required for charging the base substrate or taking out the crystal after growth. 1 hour was required for increasing the temperature and 1 hour was required for decreasing the temperature. As described above, according to the growth in this comparative example, 1 hour and 30 minutes were required for growing one sheet of Gallium Nitride substrate. Accordingly, the growth time was extremely prolonged per one sheet of substrate, compared with examples 4 and 5, thus making it impossible to provide the conductive Gallium Nitride substrate at a low cost.

The present application is based on Japanese patent application No. 2010-011123, filed on Jan. 21, 2010, the entire contents of which are hereby incorporated by reference.

What is claimed is:

1. A manufacturing method of a conductive group III nitride crystal, for growing the group III nitride crystal on a base substrate by vapor deposition at a growth rate of greater than 450 μm/hour and 2 mm/hour or less, by using a group III halogenated gas and NH₃ gas, wherein Ge is doped into the group III nitride crystal by using GeCl₄ as a doping source, so that resistivity of the group III nitride crystal is 1×10⁻³ Ωcm or more and 1×10⁻² Ωcm or less.

2. The manufacturing method of a conductive group III nitride crystal according to claim 1, wherein the NH₃ gas and GeCl₄ are mixed and used.

3. The manufacturing method of a conductive group III nitride crystal according to claim 1, wherein the base substrate is formed as a substrate, with a mask pattern formed on anyone of sapphire, gallium arsenide, silicon, Gallium Nitride, aluminium nitride, or any one of base substrates of them.

4. The manufacturing method of a conductive group III nitride crystal according to claim 2, wherein the base substrate is formed as a substrate, with a mask pattern formed on anyone of sapphire, gallium arsenide, silicon, Gallium Nitride, aluminium nitride, or any one of base substrates of them.

5. The manufacturing method of a conductive group III nitride crystal according to claim 1, wherein the group III nitride crystal is AlₓIn_{y}Ga_{1-x-y}N (0≦x≦1, 0≦y≦1, 0≦x+y≦1) crystal.

6. The manufacturing method of a conductive group III nitride crystal according to claim 2, wherein the group III nitride crystal is AlₓIn_{y}Ga_{1-x-y}N (0≦x≦1, 0≦y≦1, 0≦x+y≦1) crystal.

7. The manufacturing method of a conductive group III nitride crystal according to claim 3, wherein the group III nitride crystal is AlₓIn_{y}Ga_{1-x-y}N (0≦x≦1, 0≦y≦1, 0≦x+y≦1) crystal.

8. A manufacturing method of a conductive group III nitride substrate, comprising the steps of:
acquiring a conductive group III nitride substrate by slicing a conductive group III nitride crystal grown by the manufacturing method of the conductive group III nitride crystal according to claim 1, with an arbitrary crystal plane; and
setting a thickness to 100 μm or more and 600 μm or less by polishing both surfaces of the acquired conductive group III nitride substrate.

9. A manufacturing method of a conductive group III nitride substrate, comprising the steps of:
acquiring a conductive group III nitride substrate by slicing a conductive group III nitride crystal grown by the manufacturing method of the conductive group III nitride crystal according to claim 2, with an arbitrary crystal plane; and
setting a thickness to 100 μm or more and 600 μm or less by polishing both surfaces of the acquired conductive group III nitride substrate.

10. A manufacturing method of a conductive group III nitride substrate, comprising the steps of:
acquiring a conductive group III nitride substrate by slicing a conductive group III nitride crystal grown by the manufacturing method of the conductive group III nitride crystal according to claim 3, with an arbitrary crystal plane; and
setting a thickness to 100 μm or more and 600 μm or less by polishing both surfaces of the acquired conductive group III nitride substrate.

11. A manufacturing method of a conductive group III nitride substrate, comprising the steps of:
acquiring a conductive group III nitride substrate by slicing a conductive group III nitride crystal grown by the manufacturing method of the conductive group III nitride crystal according to claim 5, with an arbitrary crystal plane; and
setting a thickness to 100 μm or more and 600 μm or less by polishing both surfaces of the acquired conductive group III nitride substrate.

12. A manufacturing method of a conductive group III nitride substrate, wherein a maximum absolute value of a variation of a carrier concentration in a principal surface of the conductive group III nitride substrate manufactured by the manufacturing method of the conductive group III nitride substrate according to claim 8, is 1% or more and 10% or less with respect to a mean value of the carrier concentration in the principal surface.

13. A manufacturing method of a conductive group III nitride substrate, wherein a maximum absolute value of a variation of a carrier concentration in a principal surface of the conductive group III nitride substrate manufactured by the manufacturing method of the conductive group III nitride substrate according to claim 9, is 1% or more and 10% or less with respect to a mean value of the carrier concentration in the principal surface.

14. A manufacturing method of a conductive group III nitride substrate, wherein a maximum absolute value of a variation of a carrier concentration in a principal surface of the conductive group III nitride substrate manufactured by the manufacturing method of the conductive group III nitride substrate according to claim 10, is 1% or more and 10% or less with respect to a mean value of the carrier concentration in the principal surface.

15. A manufacturing method of a conductive group III nitride substrate, wherein a maximum absolute value of a variation of a carrier concentration in a principal surface of the conductive group III nitride substrate manufactured by the manufacturing method of the conductive group III nitride substrate according to claim 11, is 1% or more and 10% or less with respect to a mean value of the carrier concentration in the principal surface.

16. A conductive group III nitride substrate, which is doped with Ge,
wherein a maximum absolute value of a variation of a carrier concentration in a principal surface of the substrate is 1% or more and 10% or less with respect to a mean value of the carrier concentration in the principal surface, and resistivity is 1×10⁻³ Ωcm or more and 1×10⁻² Ωcm or less.

17. The conductive group III nitride substrate according to claim 16, which is AlₓIn_{y}Ga_{1-x-y}N (0≦x≦1, 0≦y≦1, 0≦x+y≦1) substrate.

18. The conductive group III nitride substrate according to claim 16, wherein a thickness is 100 μm or more and 600 μm or less.

19. The conductive group III nitride substrate according to claim 17, wherein a thickness is 100 μm or more and 600 μm or less.
